(19) United States
(12) Patent Application Publication
(10) Pub. No.: US 2026/0096013 A1
(43) Pub. Date: Apr. 2, 2026

(54) COMMUNICATION DEVICE FOR VEHICLE AND THERMAL MANAGEMENT INTEGRATED CONTROLLER INCLUDING THE SAME

(71) Applicant: Hanon Systems, Daejeon (KR)

(72) Inventors: Byung Kuk Kim, Daejeon (KR); Sung Jun Park, Daejeon (KR); Dong Kyu Lee, Daejeon (KR)

(21) Appl. No.: 19/345,648

(22) Filed: Sep. 30, 2025

(30) Foreign Application Priority Data
Sep. 30, 2024 (KR) 10-2024-0133205

(51) Int. Cl. H05K 1/02

(52) U.S. Cl. CPC H05K 1/0219; H05K 2201/10015; H05K 2201/1003; H05K 2201/1006

(57) ABSTRACT

A communication device, including: a printed circuit board allowing circuit elements to be mounted thereon; a communication circuit mounted on the printed circuit board so as to communicate with an electronic control unit (ECU) of a vehicle; a shield line formed around the communication circuit; and an LC filter circuit connected to the communication circuit.

### CROSS REFERENCE TO RELATED APPLICATION

The present application claims priority to Korea Patent Application No. 10-2024-0133205, filed Sep. 30, 2024, the entire contents of which are incorporated herein for all purposes by this reference.

### FIELD

The present disclosure relates to a communication device for a vehicle and a thermal management integrated controller including the same.

### BACKGROUND

Various electrical/electronic devices are equipped in the electric vehicle so as to provide safety, convenience, and infotainment of the driver. As a number of electrical/electronic devices equipped therein increases, the electrical/electronic devices occupy many places and contribute to increase in the weight, and a number of cables increases at the same time. Due to the above-described reasons, ‘an integrated controller’ has been developed so as to reduce complexity and a number of cables. The integrated controller has a concept of controlling multiple motors or actuators and the like through a single controller.

Meanwhile, unlike the conventional internal combustion engine vehicle, the electric vehicle operates the vehicle in a manner of obtaining the energy for driving from the electric energy stored in a battery module, rather than fossil fuel. The battery module includes a plurality of battery cells connected in series, and the temperature of the battery module needs to be maintained appropriately so as to effectively perform charging and discharging of the battery module. Therefore, the electric vehicle includes a thermal management system for the electric vehicle capable of cooling or heating a temperature of the battery module by checking the battery module in realtime according to an outdoor environment or a driving operation of the vehicle, etc.

A thermal management integrated controller configured to control a plurality of motors, an actuator, and the like included in the thermal management system may be provided. The thermal management integrated controller communicates with a high-level controller, and exchanges information using an internal communication between a driver stage and a controller so as to control a plurality of motors all at a time simultaneously. A communication circuit for this internal communication is provided. A Controller Area Network (CAN) communication and a Local Interconnect Network (LIN) communication are widely used as an in-vehicle communication protocol in general.

The CAN communication is widely adopted in the automobile field effectively, is a protocol standard which has long been used and characterized in the asynchronous networking which is relatively fast, and has excellent reliability by using automatic error detection and dual wire implementation. The CAN communication fits for a time-sensitive application than the LIN communication, such as a power-train, and may be implemented conveniently across a hundred or more nodes.

The LIN communication can make communication possible across forty to fifty nodes (at maximum, sixteen nodes per network segment), and has an advantage of excellent economic efficiency. However, the LIN communication has a shortcoming that the data transmission speed thereof is lower than that of the CAN communication. The LIN communication can be used in general for a work of which a low transmission speed does not matter. Because of this, the LIN communication protocol is mainly used for electronic applications such as seat positioning, mirror adjustment, climate control, internal lighting adjustment and the like. Recently, the LIN communication protocol is adopted in a diagnostic system such as a tire pressure monitoring, temperature detection and the like which do not require a realtime operation. Let alone an advantage of a low initial implementation cost, the most eye-catching advantage of the LIN communication is excellent scalability.

The conventional in-vehicle communication device needs to reduce noise received by the communication device because of a poor EMI evaluation attributable to various noises present in the vehicle.

### SUMMARY

An object of the present disclosure is to provide an in-vehicle communication device capable of improving EMC or EMI by reducing noise.

One embodiment is a communication device including a communication circuit mounted on a printed circuit board so as to transmit a drive signal from a controller to a driver, a shield line formed around a communication line being connected between an output of the communication circuit and the driver and mounted on the printed circuit board and an LC filter circuit installed at the communication line.

The LC filter circuit may include a plurality of inductors connected in series to the communication circuit and a plurality of capacitors connected in parallel to the communication circuit and the plurality of inductors.

The plurality of inductors may include a first inductor connected in series to the communication circuit, a second inductor connected in series to the first inductor and a third inductor connected in series to the second inductor.

The plurality of capacitors may include a first capacitor having one end connected to a contact between the communication circuit and the first inductor and another end connected to a ground and a second capacitor having one end connected to a contact between the first inductor and the second inductor and another end connected to the ground.

The communication circuit may be a communication circuit based on local interconnect network (LIN) protocol.

The communication line may be in the form of a bus with multiple drivers connected.

The shield line may be formed by arranging a ground pattern or metal connected to a ground.

An inductance of the first inductor and an inductance of the second inductor may be 330 μH, respectively.

A capacitance of the first capacitor may be 470 pF.

Another embodiment is a thermal management integrated controller, including a driver configured to drive a low-voltage cooling fan configured to operate for thermal management of a vehicle, a controller configured to receive a control command with respect to the driver from an high-level controller and transmit a drive signal based on the control command to the driver through the communication device and the communication device provided between the controller and the driver and transmitting the drive signal received from the controller to the driver.

According to an embodiment of the present disclosure, an in-vehicle communication circuit capable of improving EMC (EMI) by reducing noise can be provided.

In addition, according to an embodiment of the present disclosure, there is an effect that it is possible to reduce spatial noise which contributes to the EMI problem by adding an LC filter circuit to the LIN communication circuit for a low-voltage cooling fan and by shielding (GND pattern) around a line of the LIN communication.

### BRIEF DESCRIPTION OF THE DRAWINGS

FIG. 1 is a block diagram illustrating a configuration of a thermal management integrated controller of an electric vehicle.

FIG. 2 is a diagram illustrating a communication circuit according to an embodiment of the present disclosure.

FIG. 3 is a diagram illustrating an example of a shield line formed around a communication line according to an embodiment of the present disclosure.

FIG. 4 is a graph showing a test result of EMC (EMI) of a communication circuit according to an embodiment of the present disclosure.

### DETAILED DESCRIPTION

Hereinafter, embodiments of the disclosure will be described with reference to the accompanying drawings in detail.

The same or similar elements are denoted by the same reference numerals irrespective of the drawing numerals, and repetitive description thereof may be omitted.

It will be understood that when the terms “first” and “second” are used herein to describe various components, these components should not be limited by these terms. The above terms are used only to distinguish one component from another.

In the case where a component is referred to as being “connected” or “accessed” to another component, it should be understood that not only the component is directly connected or accessed to the other component, but also there may exist another component between them. Meanwhile, in the case where a component is referred to as being “directly connected” or “directly accessed” to another component, it should be understood that there is no component therebetween.

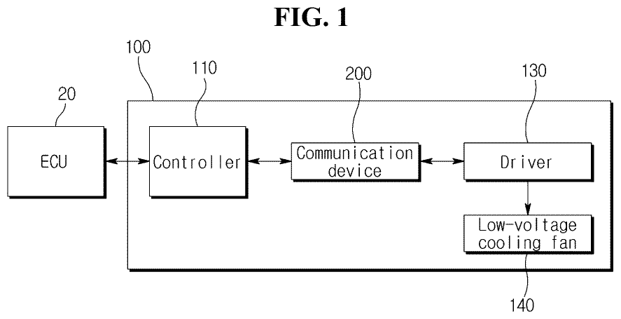

FIG. 1 is a block diagram illustrating a configuration of a thermal management integrated controller of an electric vehicle.

Referring to FIG. 1, the thermal management integrated controller of an electric vehicle 100 includes a controller 110, a communication device 200, and a low-voltage cooling fan 130. The controller 110 may communicate with an electronic control unit (ECU) 20. According to an embodiment, the controller 110 may communicate with the ECU 20 through a CAN (Controller Area Network) protocol. The CAN (Controller Area Network) refers to a standard communication protocol designed such that a micro-controller and the devices inside the vehicle can communicate with one another without a host computer, and the ECUs (electronic control unit) in the vehicle communicate with one another using the CAN protocol.

The controller 110 may receive a control command with respect to the low-voltage cooling fan 140 included in the thermal management integrated controller 100 from the ECU (electronic control unit) 20. The low-voltage cooling fan 140 may operate in conjunction with the thermal management of the electric vehicle.

When the controller 110 receives a control command with respect to the low-voltage cooling fan 140 from the ECU 20, the controller 110 may transmit a drive signal based on the control command to the driver 130 through the communication device. That is, the controller 110 may control the driver 130 configured to operate the low-voltage cooling fan 140 through the communication device 200.

The driver 130 may operate or drive a device in conjunction with thermal management of an electric vehicle, such as a motor, a water pump, and the like, for example, the low-voltage cooling fan 140. The driver 130 may operate a motor, a pump, and the like connected to the driver 130 according to a command for controlling the driver received from the ECU 20 through the controller 110.

The controller 110 may be connected to the driver 130 through the communication device 200. The communication device 200 may be a communication device configured to deliver data based on the local interconnect network (LIN) communication protocol. The LIN communication is an asynchronous communication method, and aims to transmit data of low capacity at a speed of 9600 baud rate in general, and because it is an asynchronous communication method, it does not need a clock synchronization signal required by I2C (inter integrated circuit) and SPI (serial peripheral interface) communication protocols. The LIN communication may perform both reception and transmission with only one line except the power line and the ground GND.

The communication device 100 may be positioned between the controller 110 and the driver 130, and may be vulnerable to noise and the like. In addition, the communication device 200 has to pass an EMI (electromagnetic interference) or EMC (electromagnetic compatibility) test. To this end, the communication device 200 may include an LC filter circuit 150.

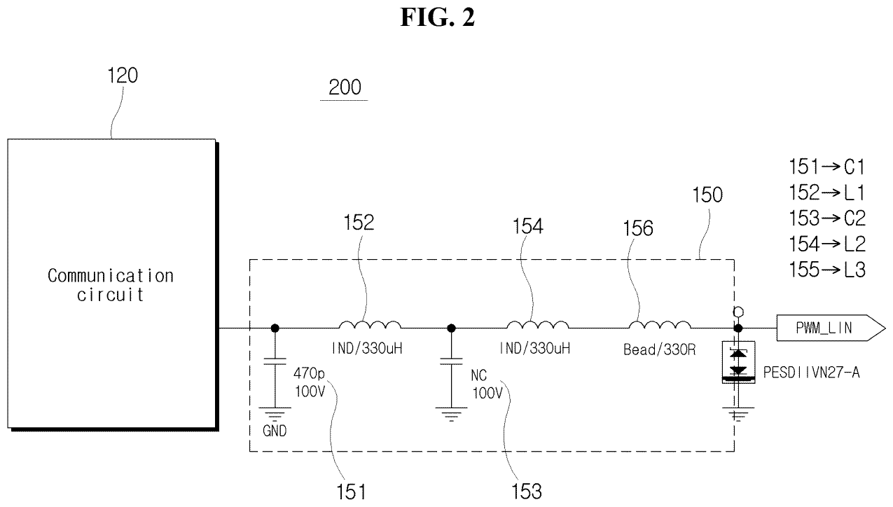

FIG. 2 is a diagram illustrating the communication device according to an embodiment of the present disclosure.

According to FIG. 2, the communication device 200 includes a communication circuit 120 and an LC filter circuit 150.

The communication circuit 120 may be provided separately on a printed circuit board (PCB), but according to another embodiment, the communication circuit 120 may be provided as a single semiconductor chip together with the controller 110.

The LC filter circuit 150 may be connected to an output of the communication circuit 120. In more detail, the LC filter circuit 150 is formed on a communication line 170 that transmits a driving signal from a communication circuit 120 to a driver 130.

The communication circuit 120 may have noise because of harmonics, inductance, and a capacity. The LC filter circuit 150 may be connected to the output of the communication circuit 120 and may remove ripple and noise caused due to communication and switching frequency that may be induced to the communication line by the communication circuit.

The LC filter circuit 150 consists of at least one inductor and at least one capacitor. In more detail, the LC filter circuit 150 includes a first inductor connected in series to the communication circuit 120, a second inductor 154 connected in series to the first inductor 152, a third inductor 156 connected in series to the second inductor 154, a first capacitor connected to a contact between the communication circuit 120 and the first inductor 152 and connected in parallel to the communication circuit 120, and a second capacitor 153 connected to a contact between the first inductor 152 and the second inductor 154 and connected in parallel to the first inductor 152. The LC filter circuit 150 may be implemented as ax-type or a T-type.

The first inductor 152, the second inductor 154, and the third inductor 156 are connected in series to the communication circuit 120, and serve to make a low-frequency signal pass and block a high-frequency signal.

The first capacitor 151 and the second capacitor 153 are connected in parallel to the communication circuit 120, and deliver a high-frequency component to the ground. In more detail, the first capacitor 151 has one end connected to a contact between the communication circuit 120 and the first inductor 152, and another end connected to the ground. The second capacitor 153 has one end connected to a contact between the first inductor 152 and the second inductor 154, and another end connected to the ground. Therefore, the first capacitor 151 and the second capacitor 153 may send the high-frequency component generated from the communication circuit 120 to the ground.

The LC filter circuit 150 makes the low-frequency signal pass and blocks the high-frequency signal. In more detail, the first inductor 152, the second inductor 154, and the third inductor 156 have a small impedance at the low frequency, and thus, make the low-frequency signal pass as it is. As the first capacitor 151 and the second capacitor 153 have a great impedance at the low frequency, they do not affect the low-frequency signal.

As the first inductor 152, the second inductor 154, and the third inductor 156 show a great impedance at the high frequency, they block the high-frequency signal. As the first capacitor 151 and the second capacitor 153 have a small impedance at the high frequency, they send the high-frequency component to the ground and remove it from the high-frequency signal. As such, the LC filter circuit 150 serves to suppress the high-frequency signal and make only the low-frequency signal to pass.

An inductance of the first inductor 152 and an inductance of the second inductance 154 may be 330 μH, respectively, and a capacitance of the first capacitor 151 may be 470 pF.

Therefore, a low frequency signal component may pass through the communication line 170, however, high frequency signal component hard to pass through the communication line 170 since an impedance of L increases and at the same time, an impedance of C decreases.

Accordingly, it is possible to remove the ripple and noise due to the switching frequency and the communication of the communication circuit 120.

Meanwhile, the communication line 170 is formed as a bus structure in which multiple drivers are connected, so that the controller 110 can transmit a driving signal to multiple drivers 130.

Further, the shield line 160 may be formed around the communication line 170.

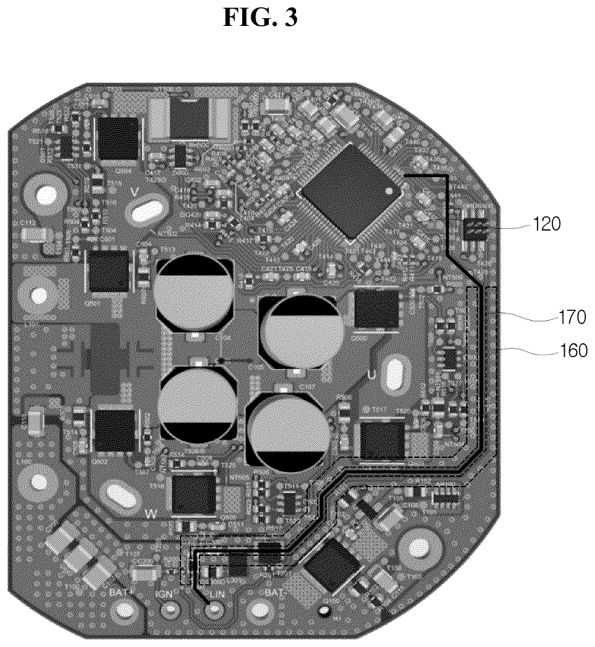

FIG. 3 is a diagram illustrating an example of the shield line formed around the communication line according to an embodiment of the present disclosure.

As illustrated in FIG. 3, the shield line 160 is formed around the communication line 170 according to the present disclosure. The shield line 160 reduces the crosstalk of the communication line 170, and the shield line 160 prevents signal flowing through the communication line 170 from being influenced by other external signals.

The shield line 160 may be formed by arranging a ground pattern or metal, connected to the ground, around the communication line 170 in the PCB. The ground pattern 160 or the metal may protect the driving signal outputted form the communication circuit 120, and maintain the circuit to be safe from an external electromagnetic interference.

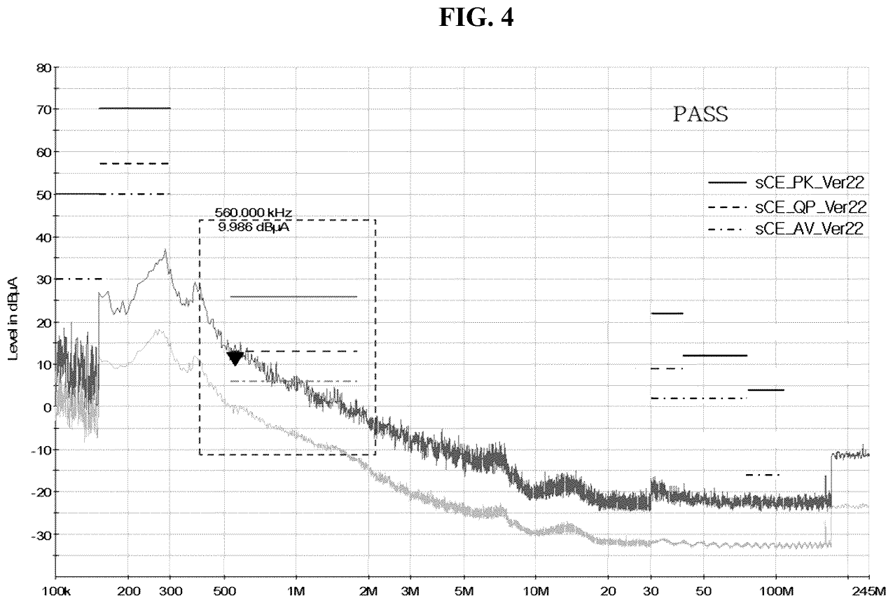

FIG. 4 is a graph showing a test result of EMC (EMI) of the communication circuit according to an embodiment of the present disclosure.

FIG. 4 shows a test result of EMI (electromagnetic interference) or EMC (electromagnetic compatibility) of the communication circuit according to an embodiment of the present disclosure.

In the graph of FIG. 4, an X axis is a frequency axis, and shows a frequency range of a tested signal, and frequencies from 100 kHz to 245 MHz are illustrated. A Y axis represents a signal intensity or an interference level, and a unit thereof is dBμA (decibel microampere). The graph means that as a value of the Y axis is greater, the interference is strong.

The graph in FIG. 4 illustrates that the communication circuit according to an embodiment of the present disclosure has passed the EMI or EMC test.

The above-described embodiments should be understood to be exemplary and not limiting in every aspect. The scope of the disclosure will be defined by the following claims rather than the above-detailed description, and all changes and modifications derived from the meaning and the scope of the claims and equivalents thereof should be understood as being included in the scope of the present disclosure.

What is claimed is:

1. A communication device, comprising:
a communication circuit mounted on a printed circuit board so as to transmit a drive signal from a controller to a driver;
a shield line formed around a communication line being connected between an output of the communication circuit and the driver and mounted on the printed circuit board; and
an LC filter circuit installed at the communication line,
wherein the LC filter circuit comprises:
a plurality of inductors connected in series to the communication circuit; and
a plurality of capacitors connected in parallel to the communication circuit and the plurality of inductors.

2. The communication device of claim 1,
wherein the plurality of inductors comprises:
a first inductor connected in series to the communication circuit;
a second inductor connected in series to the first inductor; and
a third inductor connected in series to the second inductor,
wherein the plurality of capacitors comprises:
a first capacitor having a first end connected to a contact between the communication circuit and the first inductor and a second end connected to a ground; and
a second capacitor having a first end connected to a contact between the first inductor and the second inductor and a second end connected to the ground.

3. The communication device of claim 1, wherein the communication circuit is a communication circuit based on local interconnect network (LIN) protocol.

4. The communication device of claim 3, wherein the communication line is in the form of a bus with multiple drivers connected.

5. The communication device of claim 1, wherein the shield line is formed by arranging a ground pattern or a metal connected to a ground.

6. The communication device of claim 2, wherein an inductance of the first inductor and an inductance of the second inductor is 330 μH, respectively.

7. The communication device of claim 2, wherein a capacitance of the first capacitor is 470 pF.

8. A thermal management integrated controller, comprising:
a driver configured to drive a low-voltage cooling fan configured to operate for thermal management of a vehicle;
a controller configured to receive a control command with respect to the driver from a high-level controller and transmit a drive signal based on the control command to the driver through the communication device; and
a communication device provided between the controller and the driver and transmitting the drive signal received from the controller to the driver,
wherein the communication device comprises:
a communication circuit mounted on a printed circuit board so as to transmit a driver signal received from the controller to the driver;
a shield line formed around a communication line being connected between an output of the communication circuit and the driver and mounted on the printed circuit board; and
an LC filter circuit installed at the communication line,
wherein the LC filter circuit comprises:
a plurality of inductors connected in series to the communication circuit; and
a plurality of capacitors connected in parallel to the communication circuit and the plurality of inductors.

9. The thermal management integrated controller of claim 8,
wherein the plurality of inductors comprises:
a first inductor connected in series to the communication circuit;
a second inductor connected in series to the first inductor; and
a third inductor connected in series to the second inductor,
wherein the plurality of capacitors comprises:
a first capacitor having a first end connected to a contact between the communication circuit and the first inductor and a second end connected to a ground; and
a second capacitor having a first end connected to a contact between the first inductor and the second inductor and a second end connected to the ground.

10. The thermal management integrated controller of claim 8, wherein the communication circuit is a communication circuit based on local interconnect network (LIN) protocol.

11. The thermal management integrated controller of claim 10, wherein the communication line is in the form of a bus with multiple drivers connected.

12. The thermal management integrated controller of claim 8, wherein the shield line is formed by arranging a ground pattern or a metal connected to a ground.

13. The thermal management integrated controller of claim 9, wherein an inductance of the first inductor and an inductance of the second inductor is 330 μH, respectively.

14. The thermal management integrated controller of claim 9, wherein a capacitance of the first capacitor is 470 pF.

15. The thermal management integrated controller of claim 8, wherein the communication circuit is formed as one semiconductor chip together with the controller.
